(19) United States
(12) Patent Application Publication
(10) Pub. No.: US 2002/0148562 A1
(43) Pub. Date: Oct. 17, 2002

(54) Plasma reaction apparatus and plasma reaction method

(76) Inventors: Hiromi Aoyagi, Kanagawa (JP); Toshiji Nishiguchi, Kanagawa (JP); Junichi Tamura, Kanagawa (JP)

Correspondence Address: FITZPATRICK CELLA HARPER & SCINTO, 30 ROCKEFELLER PLAZA, NEW YORK, NY, 10112, US

(21) Appl. No.: 10/112,750

(22) Filed: Apr. 2, 2002

(30) Foreign Application Priority Data
Apr. 2, 2001 (JP) 103738/2001(PAT.)

(51) Int. Cl. C23C 16/00; C23F 1/00

(52) U.S. Cl. 156/345.27; 118/723 E; 156/345.47; 118/712

(57) ABSTRACT

A plasma reaction apparatus or a plasma reaction method have a configuration in which high-potential and low-potential electrodes are placed in a reactor and in which an inorganic dielectric having a structure permitting a gas to flow therethrough is filled between the electrodes, and is adapted to generate a discharge between the electrodes to change a gas existing between the electrodes into a plasma. The plasma reaction apparatus and method are configured to control the temperature inside the reactor and thereby process the gas on the basis of a stable plasma reaction.

### BACKGROUND OF THE INVENTION

1. Field of the Invention

The present invention relates to a plasma reaction apparatus and a plasma reaction method.

2. Related Art

There is a non-thermal plasma method (or non-equilibrium plasma method) as a method of decomposing a gas containing a volatile organic compound (Volatile Organic Compound (VOC); which will be referred to hereinafter as VOC). It has been found out that the non-thermal plasma method (or non-equilibrium plasma method) had the advantages of capability of decomposing a wide concentration range of VOC at ordinary temperature and pressure in a short time, simplicity of apparatus structure, and so on. A number of methods of inducing a discharge at ordinary pressure have been developed heretofore and such methods can be generally categorized under silent discharge, surface discharge, pulsed corona discharge, and packed bed discharge.

In the silent discharge, the interelectrode distance is as short as about several mm and it is necessary to prepare a number of reactors in order to attain a stable discharge with a large quantity of a gas. The surface discharge is a discharge which occurs along a surface of a ceramic material when an AC voltage is placed between electrodes formed on a surface and inside of an inorganic substance such as ceramics or the like, and which results in an extremely localized discharge state.

A method to solve these problems is the packed bed method with a filling material of an inorganic dielectric.

The plasma apparatus of the packed bed method is so arranged that a reactor is filled with BaTiO₃ (barium titanate) or strontium titanate having a dielectric constant (or relative permittivity) (ε) of 1000 to 10000 as an inorganic dielectric and that a glow discharge is induced therein.

The VOC decomposing process with the aforementioned packed bed method plasma apparatus is effectively applicable to various VOCs. In the non-thermal plasma reaction apparatus (atmospheric pressure plasma reaction apparatus) as described, however, the temperature inside the reactor rises with time and the electric current decreases in conjunction therewith. Therefore, it was difficult to maintain a stable discharge and thus to use the apparatus continuously over a long period of time.

The rise in the temperature inside the reactor alters the current-voltage (I-V) characteristics and also poses a problem of having an adverse effect on the decomposition reaction, such as lowering of decomposition ratio (or decomposition efficiency), production of intermediate byproducts or the like. Although the temperature characteristics differ depending on the shape and capacity of the reactor, and reaction conditions, the temperature inside the reactor may reach even about 100° C. after continuous operation for about 1 to 2 hours, which may result in great lowering of the decomposition ratio.

For this reason, it is hard to maintain a stable reaction continuously in such a non-thermal plasma apparatus. Even if a high decomposition ratio is achieved temporarily by controlling (e.g., increasing) the voltage, this method has a limit, because it is not applicable to long-term operation.

A method of using an inorganic dielectric having a low dielectric constant (ε<100) is known as a method of controlling the temperature rise at a low level, but the use of the dielectric with the low dielectric constant invokes a fear of lowering of the decomposition ratio.

On the other hand, when the temperature inside the reactor is not more than 25° C., condensation of the VOC occurs depending on the type of the VOC, and the reaction may fail to proceed to a satisfactory degree in certain cases. Accordingly, it is necessary to raise the temperature when the temperature within the reactor is lower than a predetermined value or when the temperature is depressed too much by cooling. Since the optimal reaction temperature also differs depending on the type of the VOC, the state of mixing thereof, etc., the control of the temperature inside the reactor is a significant issue.

### SUMMARY OF THE INVENTION

The present invention has been accomplished to solve the above problems and an object of the invention is, therefore, to provide a plasma reaction apparatus and a plasma reaction method adapted to change a gas into a plasma and perform continuous processing by the use of the energy of the plasma and being capable of performing the processing on the basis of a stable reaction.

Under this object, the present invention provides plasma reaction apparatus and plasma reaction methods configured as follows.

A plasma reaction apparatus according to the present invention is a plasma reaction apparatus for changing a gas into a plasma, comprising: a reactor; at least a high-potential electrode and a low-potential electrode placed in the reactor, for generating a discharge between the electrodes to change a gas existing between the electrodes into a plasma; an inorganic dielectric filled between the electrodes and having such a structure as to permit the gas to flow therethrough; and a temperature controlling means for controlling temperature inside the reactor.

A plasma reaction method according to the present invention is a plasma reaction method of changing a gas into a plasma, comprising the steps of: flowing a gas through an inorganic dielectric filled between a high-potential electrode and a low-potential electrode placed in a reactor and having such a structure as to permit the gas to flow therethrough; controlling the temperature inside the reactor; and generating a discharge between the electrodes, thereby changing the gas into a plasma.

Preferably, the temperature controlling means comprises a pipe for flowing a medium through the electrode.

Preferably, the low-potential electrode is kept in a grounded state and the pipe is provided in the grounded electrode.

Preferably, the gas existing between the electrodes is changed into the plasma at ordinary pressure. The term “ordinary pressure” as herein employed is intended to embrace not also “atmospheric pressure” but also “substantially atmospheric pressure” and to specifically mean a pressure within the range of 1 atm±10% (1×10⁵ Pa±10%).

Preferably, the discharge is a glow discharge.

Preferably, the discharge decomposes a volatile organic compound existing in the gas.

Preferably, the inorganic dielectric has a clearance permitting the gas to flow therethrough and has a structure of generating the discharge in the clearance of the inorganic dielectric.

Preferably, the inorganic dielectric is a ferroelectric substance.

Preferably, the inorganic dielectric is comprised of at least one selected from barium titanate and strontium titanate.

Preferably, the inorganic dielectric has a granular shape.

Another plasma reaction apparatus according to the present invention is a plasma reaction apparatus for changing a gas into a plasma, comprising: a reactor; at least a high-potential electrode and a low-potential electrode placed in the reactor, for generating a discharge between the electrodes to change a gas existing between the electrodes into a plasma; a granular inorganic dielectric filled between the electrodes; and a pipe provided in at least one said low-potential electrode as grounded, for flowing a medium therethrough.

Another plasma reaction method according to the present invention is a plasma reaction method of changing a gas into a plasma, comprising the steps of: flowing a gas through a granular inorganic dielectric filled between a high-potential electrode and a low-potential electrode placed in a reactor; flowing a medium through a pipe provided in at least one low-potential electrode as kept in a grounded state to control the temperature inside the reactor; and generating a discharge between the electrodes, thereby changing the gas into a plasma.

Other features and advantageous effects of the present invention will be described hereinafter in detail with reference to the drawings.

### BRIEF DESCRIPTION OF THE DRAWINGS

FIG. 1 is a block diagram of a gas decomposition apparatus as an embodiment of the present invention;

FIG. 2A is a perspective view showing the appearance of a reactor in the gas decomposition apparatus as the embodiment of the present invention, and

FIG. 2B is a sectional view of the reactor in a direction parallel to the flow of a gas in the gas decomposition apparatus as the embodiment of the present invention (a cross section taken along a plane including line 2B-2B of FIG. 2A);

FIG. 3 is a sectional view of the reactor in a direction perpendicular to the flow of gas in the gas decomposition apparatus as the embodiment of the present invention (a cross section taken along line 3-3 of FIGS. 2A and 2B);

FIG. 4 is a sectional view of a grounded electrode plate in the gas decomposition apparatus as the embodiment of the present invention;

FIG. 5 is a graphical representation showing a relation between the reactor temperature and the electric current in Example 1; and

FIG. 6 is a graphical representation showing a relation between the reactor temperature and the electric current in Comparative Example 1.

### DETAILED DESCRIPTION OF THE PREFERRED EMBODIMENTS

In an embodiment of the present invention, the plasma reaction apparatus is provided with a temperature controlling means capable of cooling and heating the interior of the reactor, and is constructed to control the temperature inside the reactor within a predetermined range, so as to be able to maintain a stable discharge and, in turn, maintain a high decomposition ratio. For example, when a plasma decomposition process of VOC is continuously carried out, the variation in the temperature inside the reactor due to the discharge is suppressed by controlling the temperature with a temperature controller having the cooling function and heating function, whereby it becomes feasible to keep a stable decomposition reaction at a high decomposition ratio over a long period of time.

Specific methods for enabling the control of the temperature inside the reactor include means for circulating cold water or warm water in a pipe placed in an electrode plate so as to be capable of cooling or heating, and provision of a temperature controller capable of cooling and heating in an electrode plate. When the warm/cold water is used in the control, the cross section of a pipe for circulation of cold water or warm water can be any desired shape, for example, a circle, a polygon, or the like. The apparatus may be constructed such that the temperature and amount of water can be regulated depending on the reaction conditions and the temperature condition in the reactor. The pipe or the temperature controller can be located inside the electrode plate so as to permit uniform temperature control entirely in the reactor.

The structure of the reactor may be either a coaxial cylindrical type or a parallel plate type, and the number of layers in the reactor is allowed to change freely depending on the gas processing amounts.

By providing the grounded electrode with the cooling function and heating function, it becomes feasible to control the temperature efficiently. The I-V characteristics become approximately 20 to 30% lower in current at the reactor temperatures of about 60° C. than the initial value of electric current.

Since condensation may occur at room temperature (25° C.) or below, depending upon the types of VOCs, the reaction may fail to proceed well. Accordingly, in order to carry out the reaction while keeping a high decomposition ratio, it is necessary to maintain the temperature at 25 to 60° C., and preferably 30 to 50° C. Keeping the temperature inside the reactor constant makes it feasible to maintain the reaction at a satisfactory decomposition ratio.

The apparatus can be constructed such that the temperature inside the reactor is always monitored and is controlled so as to bring about the reaction within the temperature range optimal for the reaction.

An example of the gas decomposition apparatus in an embodiment of the present invention will be described below in further detail.

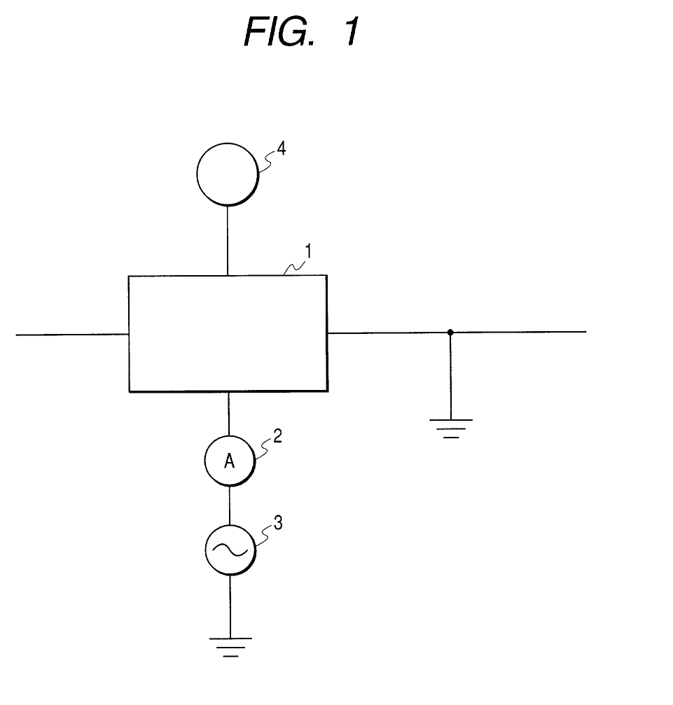

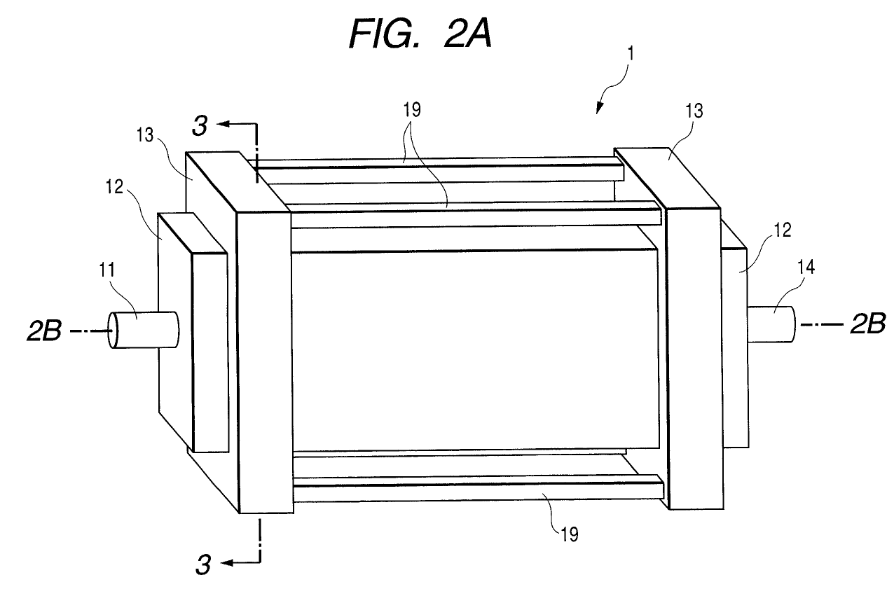

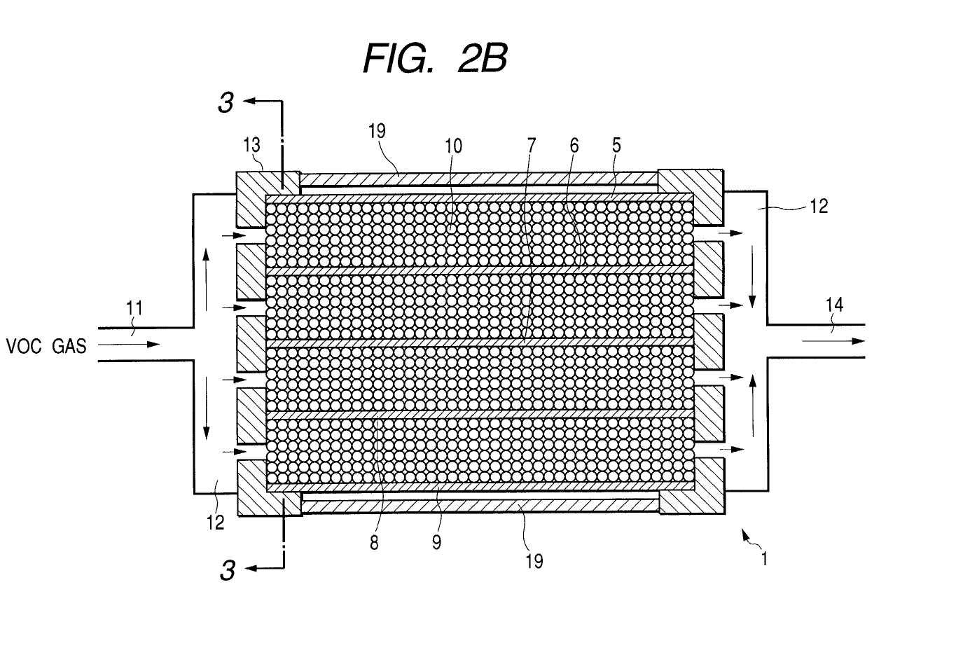

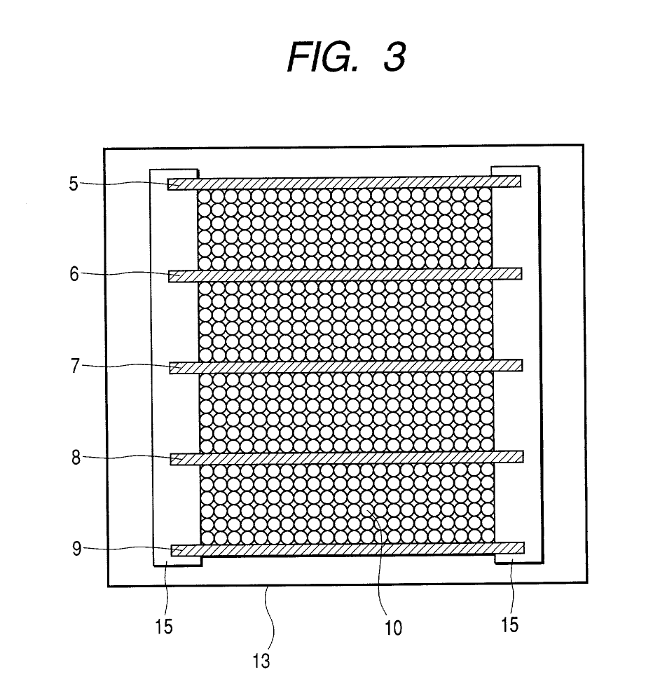

FIG. 1 is a block diagram of the gas decomposition apparatus according to the present embodiment. FIG. 2A is a perspective view showing the appearance of the reactor 1 used in the embodiment. FIG. 2B is a sectional view obtained by cutting the reactor 1 used in the present embodiment, by a plane parallel to the flow of the gas (a sectional view taken along a plane including line 2B-2B of FIG. 2A). FIG. 3 is a sectional view obtained by cutting the reactor 1 used in the present embodiment, by a plane perpendicular to the flow of the gas (a cross section along line 3-3 of FIGS. 2A and 2B).

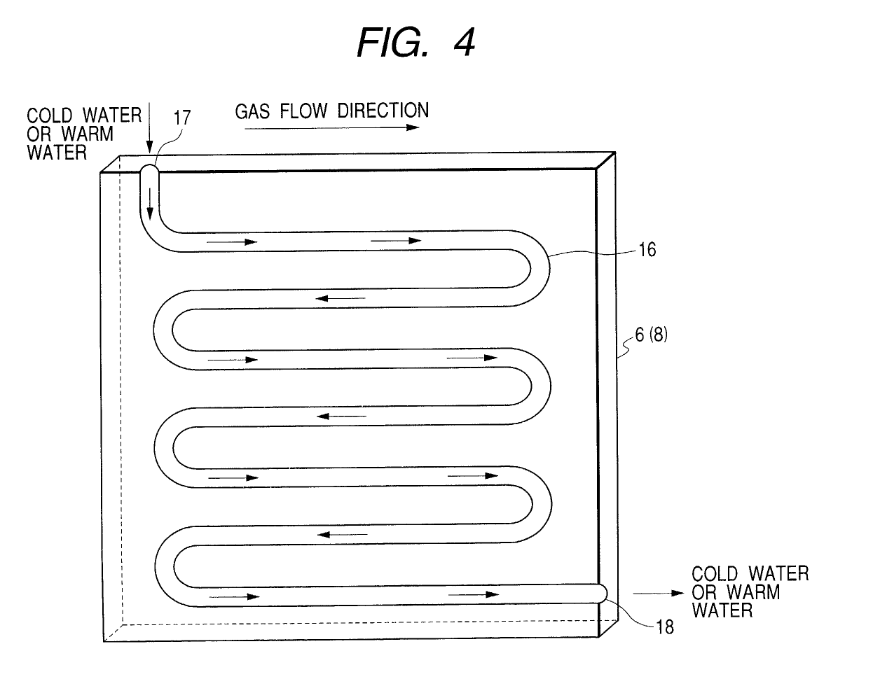

FIG. 4 is a sectional view of a grounded electrode plate in the gas decomposition apparatus according to the present embodiment, and the grounded electrode plate is provided with a pipe 16 for circulation of cold water or warm water.

As shown in FIGS. 2B and 3, the reactor 1 has five electrodes 5, 6, 7, 8, 9. Those electrodes are connected to a high potential terminal or a low potential terminal. The electrode configuration herein is such that the first electrode 5, third electrode 7, and fifth electrode 9 are high-potential electrodes and that the second electrode 6 and fourth electrode 8 low-potential electrodes.

The first electrode 5, third electrode 7, and fifth electrode 9 are connected to an AC power source 2 so that an AC voltage can be applied from the power source to the electrodes. The second electrode 6 and fourth electrode 8 are electrically grounded.

The number of the electrodes can be freely determined according to the scale of the apparatus. When the processing flow rate is large, the number of electrodes is increased whereby the apparatus scale can be enhanced without lowering the processing efficiency. The spaces between the electrodes are filled with an inorganic dielectric 10.

The inorganic dielectric is desirably selected from ferroelectrics such as barium titanate and strontium titanate having a dielectric constant of 1000 to 10000.

The preferred shape of the inorganic dielectric is a granular shape, desirably a spherical shape, having the structure permitting a gas to pass through spaces in the inorganic dielectric and inducing a discharge in clearances (or gaps) between dielectric particles, as shown in FIGS. 2B and 3.

The VOC gas enters the reactor through a reactor entrance 11 and flows into a diffusion space 12. There are no specific restrictions on the VOC gas. The diffusion space 12 is separated from the plasma space filled with the inorganic dielectric 10, by an insulator partition 13 which is made of an insulator material such as poly(tetrafluoroethylene), e.g., Teflon, and which has the gas-permeable structure like a mesh or the like, so that the inorganic dielectric 10 is prevented from entering the diffusion space 12. Incidentally, reference numeral 19 denotes columns for reinforcing the reactor 1 that are fixed between the two insulator partitions 13.

The gas flowing into the diffusion space 12 passes the insulator partition 13 to enter the plasma space filled with the inorganic dielectric. Here, an AC voltage is applied to the electrodes 1, 3, 5 to induce a glow discharge, thus generating a plasma. On this occasion, the VOC component in the VOC gas is decomposed by the energy of the plasma.

During continuous decomposition, the discharge causes variation of the temperature inside the reactor. In this case, warm water or cold water is circulated from a hot/cold water supply through the pipe 16, whereby the temperature inside the reactor can be kept constant. The pipe 16 has a circular cross section and a zigzag structure, as shown in FIG. 4, and is provided in the grounded electrodes 6, 8 as described above.

Warm water or cold water poured into a pipe inlet 17 in the upper part of the grounded electrode plates 6, 8, is circulated inside the pipe, is discharged from a pipe outlet 18 in the lower part, is further flowed back to the hot/cold water supply to be temperature-controlled, and thereafter is circulated again in the pipe, thereby controlling the temperature inside the reactor.

The temperature inside the reactor is always monitored by a temperature sensor mounted in the electrode plate. The VOC gas decomposed in the apparatus is discharged from a gas exit 14.

The following will describe examples of the present invention. The details of experiment conditions including the experiment apparatus used in the examples are given below. The decomposition ratios were determined in such a way that the gas was sampled at the entrance and the exit of the reactor into a Tedlar bag, each sample was analyzed by GCMS (gas chromatograph-mass spectrometer), and the decomposition ratio of the sample was calculated on the basis of (concentration at exit)/(concentration at entrance) of the VOC gas.

Discharge decomposition apparatus: packed bed type discharge apparatus filled with pellets of barium titanate (BaTiO₃; ε=7000) having a grain size of 3 mm;

Dimensions of reactor: electrode plates 600×120 mm, interelectrode distance 15 mm×four layers;

Sample gas: 100 ppm methanol gas;

Cold water and warm water: temperature of cold water 15° C., flow rate of cold water 25 to 30 ml/min; temperature of warm water 4020 C., flow rate of warm water 40 to 50 ml/min

### EXAMPLE 1

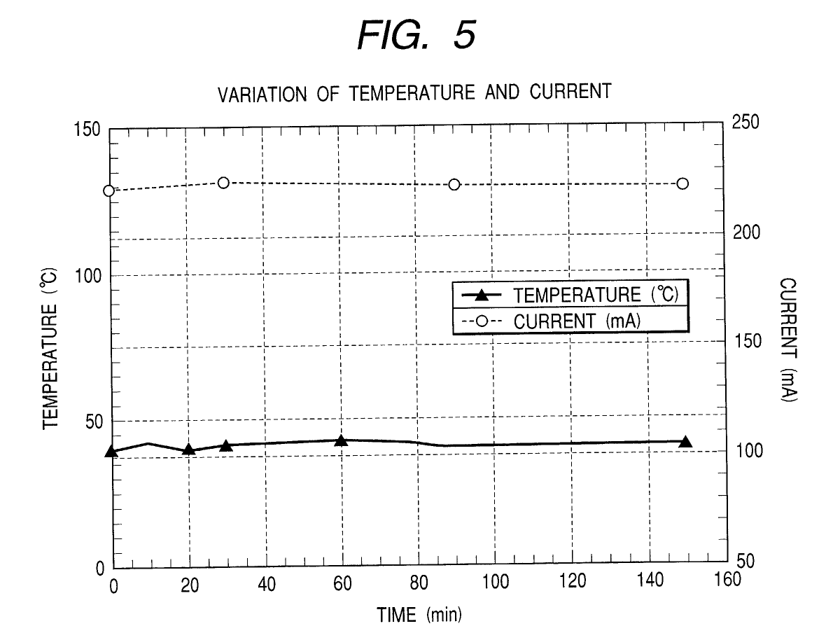

In Example 1, a voltage of 2.5 kV was applied in the reactor at an initial temperature state of 25° C. and methanol gas was allowed to flow at 80 l/min from the time when the temperature inside the reactor reached 40° C. Further, the cooling water or warm water was flowed in the pipes 16 of the grounded electrodes 6, 8, so as to control the temperature inside the reactor at 40±5° C. The variation of the electric current with the elapse of time in this case is presented in FIG. 5. It is confirmed by FIG. 5 that a stable discharge occurred in the reactor.

### EXAMPLE 2

In Example 2, methanol gas was allowed to flow at 80 l/min from the time when the temperature inside the reactor reached 40° C., and a decomposition reaction was continuously performed under the processing conditions of 2.5 kV and 230 mA. The decomposition ratios (decomposition percentages) were 89% immediately after the start of the decomposition reaction, 88% after a lapse of 60 minutes, and 89% after a lapse of 120 minutes, with the result that there appeared no variation of the decomposition ratio with the elapse of time.

### COMPARATIVE EXAMPLE 1

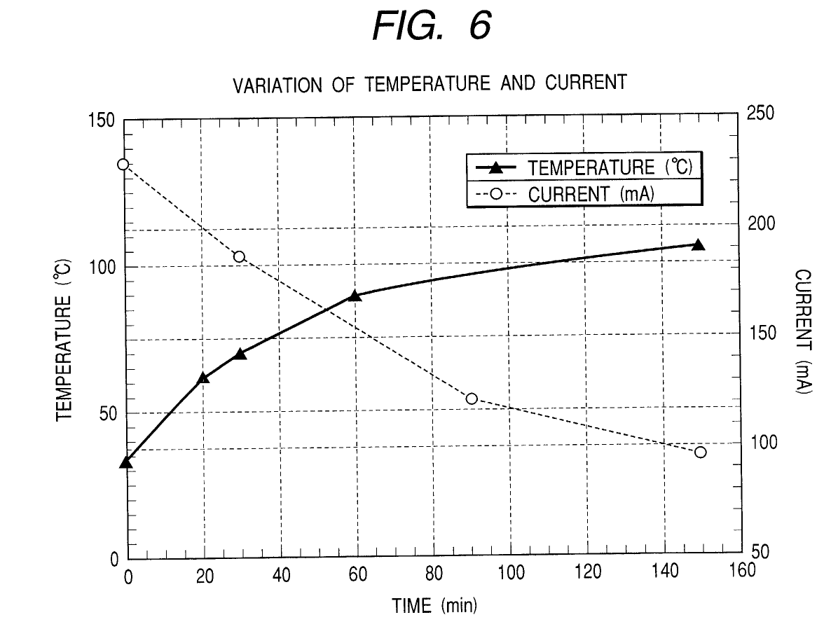

In Comparative Example 1, continuous operation was conducted under the conditions that methanol gas was flowed at 80 l/min in the reactor and a voltage of 2.5 kV was applied. During this operation, the temperature control with cooling water or warm water was not implemented. Measurement was conducted to obtain variations in the temperature inside the reactor and the electric current with the elapse of time. The results of the measurement are presented in FIG. 6. The 30-minute continuous operation resulted in a rise of the temperature inside the reactor from 27° C. to 71° C. and lowering of the electric current from 230 mA to 187 mA. After a lapse of 90 minutes, the temperature inside the reactor rose to 97° C. and the current lowered to 121 mA.

### COMPARATIVE EXAMPLE 2

In Comparative Example 2, the decomposition ratios were measured immediately after the start of decomposition, and at 30 minutes and at 90 minutes after the start of decomposition in aforementioned Comparative Example 1. The decomposition ratio was 89% immediately after the start of decomposition. The decomposition ratios were 78% after a lapse of 30 minutes and 64% after a lapse of 90 minutes, with the result that the decomposition ratio lowered with the rise of the temperature inside the reactor.

### COMPARATIVE EXAMPLE 3

In Comparative Example 3, while the temperature inside the reactor was kept at 20° C. and methanol gas was flowed at 80 l/min, the decomposition reaction was performed under the condition of 2.5 kV and 220 mA. The decomposition ratio was measured and the result was 60%.

As described above, according to the present invention, there can be realized a plasma reaction apparatus and a plasma reaction method that are adapted to change a gas into a plasma and perform continuous processing by utilization of the energy of the plasma and can implement the processing on the basis of a stable reaction.

What is claimed is:

1. A plasma reaction apparatus for changing a gas into a plasma, comprising:
a reactor;
at least a high-potential electrode and a low-potential electrode placed in the reactor, for generating a discharge between the electrodes to change a gas existing between the electrodes into a plasma;
an inorganic dielectric filled between the electrodes and having such a structure as to permit the gas to flow therethrough; and
a temperature controlling means for controlling temperature inside the reactor.

2. The apparatus according to claim 1, wherein the temperature controlling means comprises a pipe for flowing a medium through the electrode.

3. The apparatus according to claim 2, wherein the low-potential electrode is kept in a grounded state and the pipe is provided in the grounded electrode.

4. The apparatus according to claim 1, wherein the gas existing between the electrodes is changed into the plasma at ordinary pressure.

5. The apparatus according to claim 1, wherein the discharge is a glow discharge.

6. The apparatus according to claim 1, wherein the discharge decomposes a volatile organic compound existing in the gas.

7. The apparatus according to claim 1, wherein the inorganic dielectric has a clearance permitting the gas to flow therethrough and has a structure of generating the discharge in the clearance of the inorganic dielectric.

8. The apparatus according to claim 1, wherein the inorganic dielectric is a ferroelectric substance.

9. The apparatus according to claim 1, wherein the inorganic dielectric is comprised of at least one selected from barium titanate and strontium titanate.

10. The apparatus according to claim 1, wherein the inorganic dielectric has a granular shape.

11. A plasma reaction method of changing a gas into a plasma, comprising the steps of:
flowing a gas through an inorganic dielectric filled between a high-potential electrode and a low-potential electrode placed in a reactor and having such a structure as to permit the gas to flow therethrough;
controlling the temperature inside the reactor; and
generating a discharge between the electrodes, thereby changing the gas into a plasma.

12. The method according to claim 11, wherein at least one of the electrodes has a pipe and the control of the temperature inside the reactor is implemented through a medium flowing in the pipe provided in the electrode.

13. The method according to claim 12, wherein the low-potential electrode is grounded and the pipe is provided in the grounded electrode.

14. The method according to claim 11, wherein the gas existing between the electrodes is changed into the plasma at ordinary pressure.

15. The method according to claim 11, wherein the discharge is a glow discharge.

16. The method according to claim 11, wherein the discharge decomposes a volatile organic compound existing in the gas.

17. The method according to claim 11, wherein the inorganic dielectric has a clearance permitting the gas to flow therethrough and has a structure of generating the discharge in the clearance of the inorganic dielectric.

18. The method according to claim 11, wherein the inorganic dielectric is a ferroelectric substance.

19. The method according to claim 11, wherein the inorganic dielectric is comprised of at least one selected from barium titanate and strontium titanate.

20. The method according to claim 11, wherein the inorganic dielectric has a granular shape.

21. A plasma reaction apparatus for changing a gas into a plasma, comprising:
a reactor;
at least a high-potential electrode and a low-potential electrode placed in the reactor, for generating a discharge between the electrodes to change a gas existing between the electrodes into a plasma;
a granular inorganic dielectric filled between the electrodes; and
a pipe provided in at least one said low-potential electrode as grounded, for flowing a medium therethrough.

22. A plasma reaction method of changing a gas into a plasma, comprising the steps of:
flowing a gas through a granular inorganic dielectric filled between a high-potential electrode and a low-potential electrode placed in a reactor;
flowing a medium through a pipe provided in at least one said low-potential electrode as grounded to control the temperature inside the reactor; and
generating a discharge between the electrodes, thereby changing the gas into a plasma.

23. The method according to claim 22, wherein the medium is water.

24. The method according to claim 22, wherein an organic compound existing in the gas is decomposed by the change of the gas into the plasma.
